(19) United States
(12) Patent Application Publication
(10) Pub. No.: US 2012/0021297 A1
(43) Pub. Date: Jan. 26, 2012

(54) LITHIUM ION BATTERY

(75) Inventors: Otto Hauser, Esslingen (DE); Hartmut Frey, Esslingen (DE)

(73) Assignee: Dritte Patentporfolio Beteiligungesellschaft mbH & Co. KG, Schoenefeld/Waltersdorf (DE)

(21) Appl. No.: 13/125,178

(22) PCT Filed: Oct. 19, 2009
(86) PCT No.: PCT/EP2009/063682

§ 371 Date: Jun. 2, 2011

(30) Foreign Application Priority Data
Oct. 20, 2008 (DE) 10 2008 052 141.8
Oct. 31, 2008 (DE) 10 2008 054 187.7

(51) Int. Cl. H01M 10/02; B05D 5/12; H01M 4/64; H01M 4/38; H01M 4/505; H01M 4/525; H01M 4/583; C23C 14/14; H01M 4/66; B82Y 30/00

(52) U.S. Cl. 429/303; 427/525; 427/58; 429/188; 977/755

(57) ABSTRACT

A lithium battery comprising an anode and a cathode structure separated from one another by a membrane structure. The membrane structure comprises a layer which is only conductive to lithium ions and which is characterized by the property of having sufficient mechanical stability at temperatures higher than 150° C. to prevent a local short circuit between the anode and the cathode structure.

### CROSS-REFERENCE TO RELATED APPLICATIONS

This application is a Section 371 of International Application No. PCT/EP2009/063682, filed Oct. 19, 2009, which was published in the German language on Apr. 29, 2010, under

International Publication No. WO 2010/046346 A1 and the disclosure of which is incorporated herein by reference.

### BACKGROUND OF THE INVENTION

Lithium ion batteries essentially have three layers. One of the layers is the cathode layer, another layer is the anode layer, and between those layers is a film or membrane layer to keep the cathode and anode layers separated.

The cathode layer consists of a metallic film and a nanocrystalline layer deposited thereon. The nanocrystalline layer is selected from materials able to store metallic lithium. This storage occurs either chemically or by depositing metallic lithium onto the boundary with the metallic electrode. A known material for storing lithium ions is CoO₂ which can intercalate and also release lithium ions.

The anode layer consists of nanocrystalline silicon or carbon. The anode layer is provided with a metallic conducting layer on the side facing away from the cathode side.

The membrane or film situated between these two layers is to electrically and mechanically isolate the cathode and the anode from each other. Only lithium ions can pass through the film or membrane; i.e. the intermediate layer between the cathode and the anode layer conducts lithium ions. The electrical conduction between the anode and the cathode layer occurs inside the lithium battery via lithium ions, electrons flow in the lithium battery load circuit or come from the voltage source during charging.

When discharging, the LiCoO₂ molecules accommodate the lithium ions, resulting in a positively charged lithium atom and a free electron. The electron flows through the anode connection and the consumer to the cathode while the positively charged lithium ion passes through the membrane to the cathode. The current flow direction is reversed during charging, whereby the lithium ion recombines with the electron at the anode to a neutral lithium atom stored in the anode layer.

To date, PEO (polyethylene oxide) has been used as the material for the film or membrane. This material is sufficiently stable to approximately 150° C. so as to ensure the desired mechanical and electrical separation between the two electrodes. At higher temperatures, the PEO liquefies, at least locally, to the extent that there are short-circuits in those areas between the two electrodes, making the cell unusable.

The membrane's heat resistance between the electrodes is thus an essential determining property defining the maximum voltage charge that can be applied to the cell or the cell's maximum voltage load. The charging process is thereby the more critical procedure, because charging the lithium battery is an exothermic process, such that the heating of the lithium battery is fed by the exothermic electrochemical process and the heat losses from the internal resistance of the lithium battery. The higher the heat resistance of the membrane, the higher the charging currents can be, which in turn has a substantial influence on the charging time.

### BRIEF SUMMARY OF THE INVENTION

Proceeding from this point, an object of the present invention is to develop a lithium battery having a membrane of higher heat resistance. This object is achieved in accordance with the invention by a lithium battery having:
a cathode comprising a metallic conducting substrate and a polycrystalline layer situated on the substrate;
an ion-conducting membrane structure comprising at least one lithium conducting layer;
an anode comprising a polycrystalline layer and a metallic conducting layer, wherein the polycrystalline layer faces the membrane structure;
wherein the lithium conducting layer is a thin, gas-tight polymer film, which is physically treated such that channels and/or lithium ions or lithium atoms are introduced in the lithium-conducting layer by bombardment with lithium ions or lithium atoms.

The novel lithium battery has a multi-layered cathode. The cathode comprises a metallic conducting layer and a polycrystalline layer deposited thereon. The anode is likewise multi-layer and comprises a polycrystalline layer as well as a metallic conducting layer. The cathode and the anode are separated from each another by a membrane structure exhibiting a heat resistance higher than 150° C.

Both polycrystalline layers are preferably nanocrystalline layers.

The metallic conducting layer of the cathode or the anode can be a nickel layer or a stainless steel layer. That metallic conducting layer which is the last to be deposited and thus does not serve as a substrate, can be deposited galvanically, while the other layer serves as a stabilizing substrate.

The materials for the polycrystalline cathode layer can be selected from among the substances TiS₂, MnO₂, NiMn and CoO₂.

The materials for the polycrystalline anode layer can be selected from among the substances C, Si, LiAl, LiC and LiNi.

Depositing the nanocrystalline layers for the cathode and the anode is known. Any suitable method is conceivable for this purpose, for example ion plating (ion beam mixing).

The ion-conducting membrane structure can be single or double layered. In the case of a double-layered membrane, this consists of a porous layer material and a layer which only conducts lithium ions. The layer which conducts lithium ions is considerably thinner than the porous layer, which serves as mechanical protection for the thinner lithium ion-conducting layer.

The lithium ion-conducting layer can be a layer which is initially impermeable, even to lithium ions, immediately after being deposited. A suitable physical treatment then makes this thin and initially impermeable layer able to conduct lithium ions. To this end, the layer is bombarded with lithium atoms or lithium ions, for example in an ion beam process, wherein the speed of the lithium ions is set such that they either penetrate the membrane and leave channels or penetrate through most of the layer yet remain stuck in the layer. The remaining membrane thickness between the implanted lithium atom and the corresponding electrode or protective film layer should not be larger than 20 nm, while the film itself can exhibit a layer thickness of between 10 and 20 μm.

Another possibility of creating the membrane layer consists of spraying on the base material for the polymer layer by high pressure atomization combined with ultrasonic atomization. Li₃PO₄ or Li₃P or silicon nanoparticles are added to the polymer material. A suitable method is described in German Patent Application Publication DE 10 2008 047 955, to which reference is herewith made.

The desired polymerization occurs when the polymer material is sprayed into a high frequency plasma situated on the surface of the substrate.

In each case, polymers are used which have a glass transition temperature higher than 150° C. The described methods enable polymers with a correspondingly high glass transition temperature, which are not inherently conductive to ions, to thereby be made conductive to ions without any adverse change to their glass transition point.

A further possibility of creating the membrane consists of using a covalent-bonding gel electrolyte. The electrolyte is based on star-shaped and linear polymer chains. As the scaffold, material which is conductive to lithium ions and having a glass transition point below 150° C. can in turn be embedded in the gel electrolyte structure. By combining the heat-resistant scaffold with the low melting point material ensuring ion conductivity, a membrane is produced which, as a whole, has a heat resistance higher than 150° C.

Lastly, a sol-gel layer can be deposited by spin or dip coating. The sol-gel layer contains ZrO₂ particles as well as H₃PO₄ or Li₃PO₄. Sol-gel refers to a gel having a colloidal dispersion of solids in liquid.

### BRIEF DESCRIPTION OF THE SEVERAL VIEWS OF THE DRAWINGS

The foregoing summary, as well as the following detailed description of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown. In the drawings:

FIG. 1 is a schematic cross-sectional view showing the layer structure of a lithium ion battery according to an embodiment of the present invention.

FIG. 1A is an enlarged detail view of the circled portion A in FIG. 1, schematically showing the membrane structure.

The drawings depict the principle design of the lithium ion battery. The drawings are not to scale and are oversimplified in order to enable a better understanding of that which is essential to the invention.

### DETAILED DESCRIPTION OF THE INVENTION

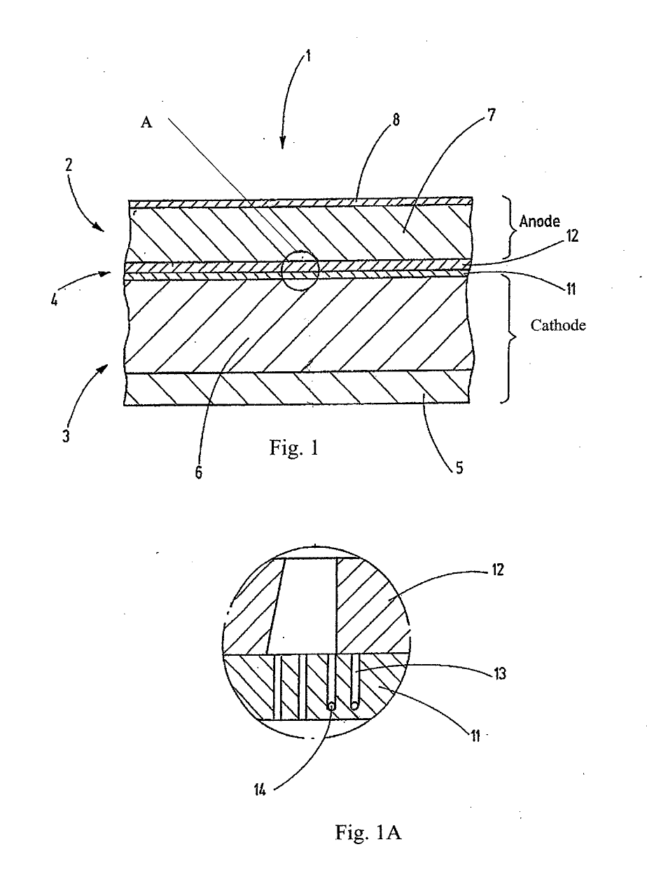

FIG. 1 shows the schematic structure of a lithium ion battery 1. The lithium ion battery comprises an anode arrangement 2 as well as a cathode arrangement 3, likewise formed as a layer. A membrane structure layer 4 is situated between the anode and the cathode 2, 3, which separates the anode layer 2 from the cathode layer 3 to prevent an electrical short circuit between the two.

The cathode layer 3 consists of a substrate 5 which is, for example, nickel or an inconel band (stainless steel). This band-shaped substrate 5 supports a polycrystalline layer 6 able to accommodate lithium ions in a crystalline lattice, which one skilled in the art refers to as intercalation. The material for the polycrystalline layer 6 can be selected from among substances such as MnO₂, COO₂, NiMn, or other substances having similar intercalation properties.

Known methods are used to deposit the polycrystalline layer 6 on the substrate 5, for example ion beam mixing in which an ion beam bombards a respective target consisting of the substance used to produce the nanocrystalline layer. The bombarding ions strip away the material and transport it to substrate 5, where it creates a corresponding nanocrystalline layer.

The membrane layer 4 consists of two organic layers; their structure and how they are produced will be detailed further below.

The anode layer 2 ultimately on the membrane layer 4 consists, in turn, of a polycrystalline layer 7 and a metallically conducting layer 8. The polycrystalline layer 7 consists of a material selected from the substances CSi, LiAl, LiC or LiNi. The material is selected such that metallic lithium can be embedded within it.

The depositing of the polycrystalline layer 7, which represents the active part of the anode layer 2, can ensue in the same way as described above in conjunction with layer 6.

Lastly, layer 8 is galvanically deposited, specifically by chemical galvanizing. Layer 8 is, for example, a metallic nickel layer.

As a whole, the structure depicted in FIG. 1 has a thickness of between 30 μm and 100 μm.

The membrane layer 4 situated between the anode 2 and the cathode 3 should, on the one hand, be conductive to lithium ions but, on the other hand, should also be stable enough that the membrane layer will not be damaged during coating or during the subsequent operation. In addition, the membrane layer 4 must be sufficiently temperature-stable so as to retain its mechanical and electrical properties when the cell heats up during operation. As noted at the outset, the charging process is thereby the more critical process, because the charging process is an exothermic process such that the heat loss and the resulting heat summate in the chemical process. The discharging process, on the other hand, is an exothermic chemical process in which the electrical heat loss is partly depleted in the exothermic process, which contributes to keeping the temperature of the cell lower at the same current during discharging.

What the expert understands as “conductive to lithium ions” is a membrane which, put simply, works like a sieve only allowing lithium ions, but not other ions, to pass.

The theory of lithium cells will not be discussed any further here. The electrophysical processes which occur in the cell are known to one skilled in the art and need no further discussion here.

The membrane layer 4 is double-layered consisting of a thin layer 11 and a thicker layer 12. The thin layer 11 has a thickness of between 5 μm and 20 μm, while the thicker layer has a thickness of between 10 and 20 μm. The thicker layer 12 is used in the production process of the lithium cell and is to protect the thin layer 11 from damage during the further production process. The thicker layer 12 is thus “porous,” i.e., it has passages allowing not only lithium ions to pass through.

The thicker layer 12 can consist of a polysulfone film, for example. A polysulfone film is not intrinsically porous. In order to make it porous, it is stretched subsequently in the production process. This creates the desired through openings. Subsequently, the film thus obtained is deposited on the thin layer 11, for example by vacuum calendering.

The layer 11 important to the function of the lithium cell 1 has a thickness of 2 to 19 μm, preferably 2 to 5 μm. The material for layer 11 can be polysulfone, polybenzimidazole or polyphosphazene. This material is not intrinsically conductive to lithium ions after being deposited on layer 6. In order to create the desired ion conductivity, the produced layer is bombarded with lithium ions or lithium atoms. In the process, the lithium ions or atoms penetrate into layer 11 and created the desired channels 13 there. It is not necessary for the channels 13 to break through to layer 6. It is sufficient when the lithium atoms, as represented by 14, lodge in the sack-shaped channel 13. The distance between the sack-shaped end of channel 13 and layer 6 should be between 10 and 20 nm. A subsequent forming process would drive the lithium ions completely through the material of layer 11.

The lithium ion-conducting deposit or layer 11 of the membrane structure 4 created in this manner is subsequently protected by layer 12, structured as described above.

The above-noted base materials for layer 11 of the membrane layer have in total a glass transition temperature above 150° C., so as to also ensure proper operation of the lithium cell at higher temperatures. The lithium cell produced according to the invention thus permits a higher operating temperature than lithium cell structures with PEO in accordance with the prior art. The inventive batteries can accordingly be subjected to higher currents both when being charged as well as when being discharged.

The novel lithium batteries are furthermore characterized by a lower internal resistance, since the “insulating” membrane between the anode and cathode is thinner than in the prior art. The thickness of the membrane has an influence on the internal resistance. The less thick the membrane is, the less also is the cell's internal resistance, which in turn contributes to keeping the heat loss low when charging.

The lithium ion-conducting layer 11 of membrane layer 4 can also be produced, for example, by spraying the above-noted material with a substance additive selected from among the group of Li₃PO₄, Li₃P or silicon nanoparticles onto layer 12 under high pressure. The desired polymerization ensues through the effect of high-frequency plasma on the sprayed-on material. The embedded molecules later ensure the desired channeling through which the lithium ions can move. A method of high-pressure atomizing is described, for example, in DE 10 2008 047 955. Reference is made to this prior publication here in order to avoid unnecessary repetition.

A further possibility of creating the ion-conducting layer 11 of the membrane layer 4 comprises introducing a binding gel electrolyte consisting of star-shaped or linear polymer chains. This substance forms a mechanical scaffold which is also sufficiently mechanically stable at temperatures above 150° C. The interspaces in the scaffold are filled with PEO, which is innately conductive to lithium ions. On the other hand, the embedded PEO prevents the passage of other atoms, such that a membrane layer 4 is created which is only conductive to lithium ions, and that also at temperatures higher than 150° C., and thus at a temperature higher than the glass transition point of PEO. The gel electrolyte scaffold prevents the liquefied PEO from dissolving locally and thus allowing a short circuit to occur between the anode and the cathode.

A further possibility of creating the desired lithium ion-conducting layer 11 provides for creating a membrane by depositing a sol-gel layer. This is selected from the substances polybenimidazole or polyphosphazene in combination with ZrO₂ particles. This material is applied employing a spin or dip coating method and subsequently polymerized. The embedded zirconium oxide molecules ensure the corresponding lithium ion conductivity.

In sum, a lithium battery comprises an anode and a cathode structure separated from one another by a membrane structure. The membrane structure comprises a layer which is only conductive to lithium ions and which is characterized by the property of having sufficient mechanical stability at temperatures higher than 150° C. to prevent a local short circuit between the anode and the cathode structure.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

1.-22. (canceled)

23. A lithium ion battery comprising:
a cathode comprising a metallic conducting substrate and a first polycrystalline layer situated on the substrate,
an ion-conducting membrane structure comprising at least one lithium-conducting layer, and
an anode comprising a second polycrystalline layer and a metallic conducting layer, the second polycrystalline layer facing the membrane structure,
wherein the lithium-conducting layer comprises a polymer film comprising a polymer having a glass transition temperature higher than 150° C. and being conductive to lithium ions due to physical treatment.

24. The lithium ion battery according to claim 23, wherein the physically treatment of the polymer film is such that channels and/or lithium ions or lithium atoms are introduced in the lithium-conducting layer by bombardment with lithium ions or lithium atoms.

25. The lithium ion battery according to claim 24, wherein a clearance between an introduced lithium atom and the anode, cathode or other layer adjoining the lithium-conducting layer is not greater than 20 nm

26. The lithium ion battery according to claim 23, wherein the lithium-conducting layer has a thickness of from 2 to 19 μm.

27. The lithium ion battery according to claim 23, wherein the lithium-conducting layer has a thickness of from 2 to 5 μm.

28. The lithium ion battery according to claim 23, wherein the ion-conducting membrane structure comprises a second layer which is porous.

29. The lithium ion battery according to claim 28, wherein the lithium-conducting layer is thinner than the second layer.

30. The lithium ion battery according to claim 28, wherein the second layer has a thickness of between 10 and 20 μm.

31. The lithium ion battery according to claim 23, wherein the metallic conducting substrate comprises a material selected from nickel and stainless steel.

32. The lithium ion battery according to claim 23, wherein at least one of the first and second polycrystalline layers comprises a nanocrystalline layer.

33. The lithium ion battery according to claim 23, wherein the first polycrystalline layer comprises a material selected from MnO₂, CoO₂ and NiMn.

34. The lithium ion battery according to claim 23, wherein ion-conducting membrane structure comprises a material selected from polyetherketone, polysulfone, polyimide, polyethersulfone, polybenzimidazole, and polyphosphazene.

35. The lithium ion battery according to claim 23, wherein the second polycrystalline layer comprises a material selected from C, Si, LiAl, LiC, and LiNi.

36. The lithium ion battery according to claim 23, wherein the ion-conducting membrane structure comprises polyethylene oxide.

37. The lithium ion battery according to claim 23, wherein the lithium-conducting layer contains covalent-bonding gel electrolyte comprising star-shaped or linear polymer chains in which lithium ion-conducting material is embedded.

38. A method for producing a lithium ion battery comprising:
a cathode comprising a metallic conducting substrate and a first polycrystalline layer situated on the substrate,
an ion-conducting membrane structure comprising at least one lithium-conducting layer, and
an anode comprising a second polycrystalline layer and a metallic conducting layer, the second polycrystalline layer facing the membrane structure,
the method comprising depositing the lithium-conducting layer as a polymer film on a second layer of the membrane structure, the polymer film comprising a polymer having a glass transition temperature higher than 150° C., and subsequently physically treating the polymer film such that the polymer film is conductive to lithium ions.

39. The method according to claim 38, wherein the physical treatment comprises bombarding the polymer film with lithium ions or lithium atoms.

40. The method according to claim 38, wherein the polymer film is a thin, gas-tight polymer film.

41. The method according to claim 40, wherein the lithium-conducting layer is deposited on the second layer of the membrane structure by dip or spin coating.

42. The method according to claim 38, wherein the lithium-conducting layer is deposited onto the second layer of the membrane structure by high pressure atomization spraying.

43. The method according to claim 42, wherein the lithium-conducting layer is sprayed onto the second layer of the membrane structure with addition of substances selected from Li₃PO₄, Li₃P and silicon particles.

44. The method according to claim 38, wherein the lithium-conducting layer is deposited on the anode or on the cathode.

45. The method according to claim 38, wherein the lithium-conducting layer is deposited on the second layer of the membrane structure as a sol-gel layer comprising a polymer selected from polybenzimidazole and polyphosphazene, wherein the polymer is combined with ZrO₂ particles.
